(19) United States
(12) Patent Application Publication
(10) Pub. No.: US 2020/0273823 A1
(43) Pub. Date: Aug. 27, 2020

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventors: Hsiang Chi CHEN, Kaohsiung (TW); Cheng-Nan LIN, Kaohsiung (TW)

(73) Assignee: Advanced Semiconductor Engineering, Inc., Kaohsiung (TW)

(21) Appl. No.: 16/287,962

(22) Filed: Feb. 27, 2019

(51) Int. Cl. H01L 23/66; H01L 23/498; H01L 23/00; H01L 21/48; H01L 21/78; H01Q 1/22

(52) U.S. Cl. CPC H01L 23/66; H01L 23/49827; H01L 23/49833; H01L 23/49838; H01L 23/562; H01L 24/16; H01L 2924/3511; H01L 21/486; H01L 21/78; H01Q 1/2283; H01L 2223/6677; H01L 2224/16157; H01L 21/4857

(57) ABSTRACT

A semiconductor device package includes a first substrate, a second substrate, an electrical contact and a support element. The first substrate has a first surface. The second substrate has a first surface facing the first surface of the first substrate. The electrical contact is disposed between the first substrate and the second substrate. The support element is disposed between the first substrate and the second substrate. The support element includes a thermosetting material.

### BACKGROUND

### 1. Technical Field

The present disclosure relates generally to a semiconductor device package and a method of manufacturing the same, and to a semiconductor device package including two substrates to define a cavity and a method of manufacturing the same.

### 2. Description of the Related Art

The development of mobile communication has caused demand for high data rates and stable communication quality, and high frequency wireless transmission (e.g., 28 GHz or 60 GHz) has become one of the most important topics in the mobile communication industry. In order to achieve such high frequency wireless transmission, the signal can be transmitted in a band having wavelengths from about ten to about one millimeter (“millimeter wave,” or “mmWave”). However, the signal attenuation is one of the problems in millimeter wave transmission.

### SUMMARY

In one or more embodiments, according to one aspect, a semiconductor device package includes a first substrate, a second substrate, an electrical contact and a support element. The first substrate has a first surface. The second substrate has a first surface facing the first surface of the first substrate. The electrical contact is disposed between the first substrate and the second substrate. The support element is disposed between the first substrate and the second substrate. The support element includes a thermosetting material.

In one or more embodiments, according to another aspect, a semiconductor device package includes a first substrate, a second substrate, an electrical contact and a support element. The first substrate has a first surface. The second substrate has a first surface facing the first surface of the first substrate. The electrical contact is disposed between the first substrate and the second substrate. The support element is disposed between the first substrate and the second substrate. The curing temperature of the support element is higher than the melting point of the electrical contact.

In one or more embodiments, according to another aspect, a method of manufacturing a semiconductor device package includes (a) providing a first substrate having a first surface; (b) disposing one or more support elements on the first surface of the first substrate; (c) disposing a second substrate on the support elements, the second substrate having one or more electrical contacts on a first surface of the second substrate facing the first surface of the first substrate; (d) providing a first temperature to melt the electrical contacts; and (e) providing a second temperature to cure the support elements. The second temperature is higher than the first temperature.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1A illustrates a cross-sectional view of a semiconductor device package in accordance with some embodiments of the present disclosure.

FIG. 1B illustrates a top view of a substrate shown in FIG. 1A in accordance with some embodiments of the present disclosure.

FIG. 1C illustrates a top view of a substrate shown in FIG. 1A in accordance with some embodiments of the present disclosure.

FIG. 1D illustrates a top view of a substrate shown in FIG. 1A in accordance with some embodiments of the present disclosure.

FIG. 1E illustrates a top view of a substrate shown in FIG. 1A in accordance with some embodiments of the present disclosure.

FIG. 1F illustrates an enlarged view of a portion of a support element shown in FIG. 1A in accordance with some embodiments of the present disclosure.

FIG. 2A, FIG. 2B and FIG. 2C illustrate a method of manufacturing a semiconductor device package in accordance with some embodiments of the present disclosure.

FIG. 3A, FIG. 3B, FIG. 3C, FIG. 3D, FIG. 3E and FIG. 3F illustrate a method of manufacturing a semiconductor device package in accordance with some embodiments of the present disclosure.

Common reference numerals are used throughout the drawings and the detailed description to indicate the same or similar elements. The present disclosure will be readily understood from the following detailed description taken in conjunction with the accompanying drawings.

### DETAILED DESCRIPTION

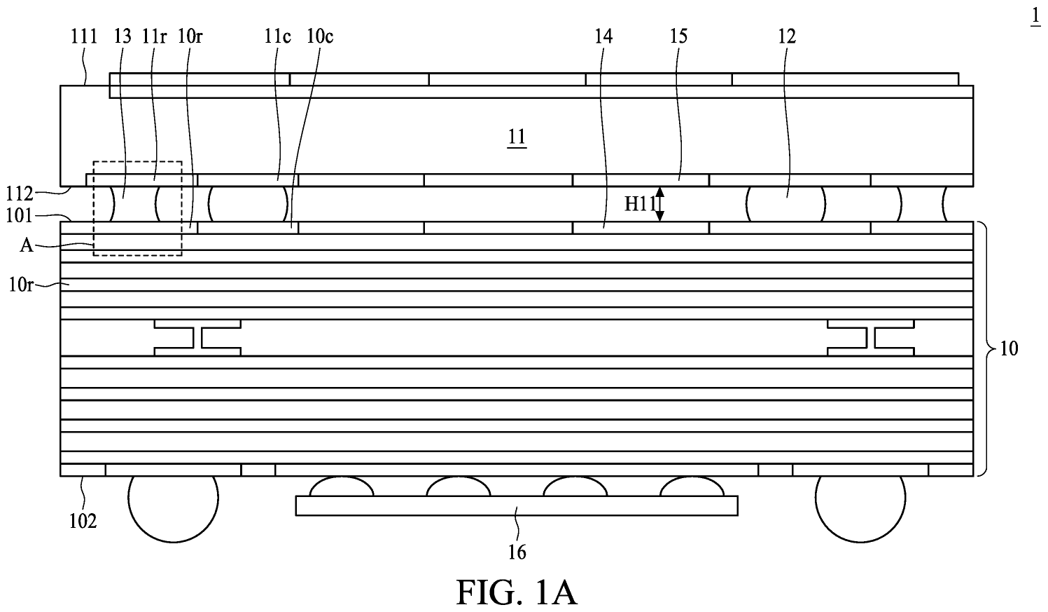

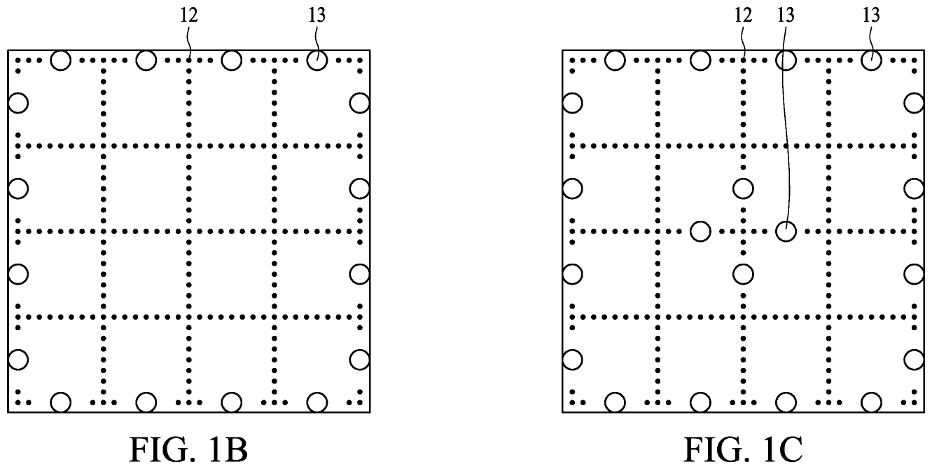

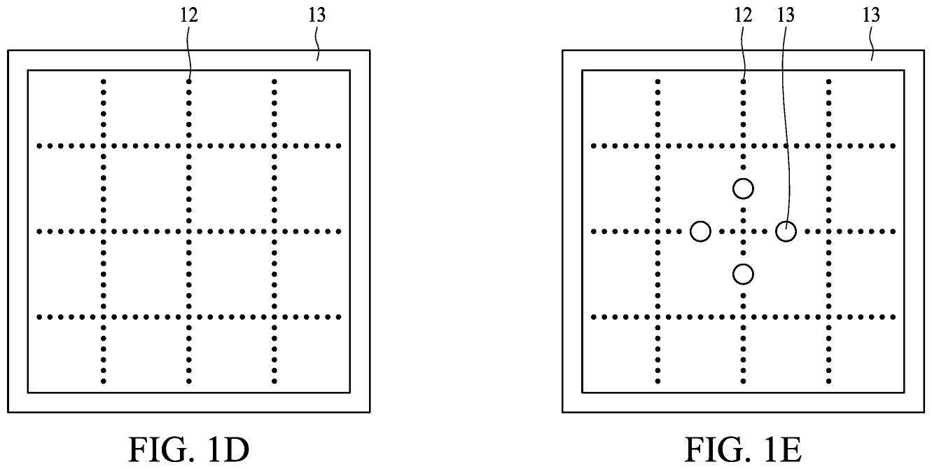

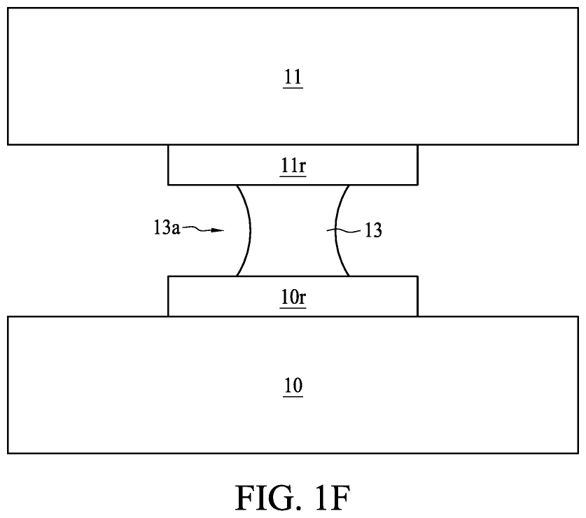

FIG. 1A illustrates a cross-sectional view of a semiconductor device package 1 in accordance with some embodiments of the present disclosure. The semiconductor device package 1 includes substrates 10, 11, one or more electrical contacts 12, one or more support elements 13, antenna patterns 14, 15 and an electronic component 16.

The substrate 10 may be, for example, a printed circuit board, such as a paper-based copper foil laminate, a composite copper foil laminate, or a polymer-impregnated glass-fiber-based copper foil laminate. The substrate 10 may include an interconnection structure 10r, such as a redistribution layer (RDL) or a grounding element. In some embodiments, the substrate 10 may be a single-layer substrate or multi-layer substrate which includes a core layer and a conductive material and/or structure disposed on a surface 101 (also can be referred to as a top surface or a first surface) and a surface 102 (also can be referred to as a bottom surface or a second surface) of the substrate 10. The conductive material and/or structure may include a plurality of traces. The substrate 10 may include one or more conductive pads 10c in proximity to, adjacent to, or embedded in and exposed at the surface 101 of the substrate 10. The substrate 10 may include a solder resist 10r (or solder mask) on the surface 101 of the substrate 10 to fully expose or to expose at least a portion of the conductive pads 10c for electrical connections. For example, the solder resist 10r may cover a portion of the conductive pads 10c.

The antenna pattern 14 is disposed on the surface 101 of the substrate 10. In some embodiments, the antenna pattern 14 includes a plurality of antenna elements. For example, the antenna pattern 14 may include an array of antenna elements. In some embodiments, the antenna 14 may include an M×N array of antenna elements, where M and N are integers greater than 0.

The electronic component 16 is disposed on the surface 102 of the substrate 10. In some embodiments, the electronic component 16 electrically connected to the antenna pattern 14 through the interconnection structure 10r within the substrate 10. The electronic component 16 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The electronic component 16 may be electrically connected to the substrate 10 (e.g., to the conductive pads), and electrical connection may be attained by way of flip-chip or wire-bond techniques.

The substrate 11 is disposed over the substrate 10 and spaced apart from the substrate 10. In some embodiments, the substrate 11 can be the same as or different from the substrate 10 depending on design specifications. The substrate 11 has a surface 111 and a surface 112 opposite to the surface 111. The surface 112 of the substrate 11 faces the surface 101 of the substrate 10. In some embodiments, the surface 111 of the substrate 11 is referred to as a top surface or a second surface, and the surface 112 of the substrate 11 is referred to as a bottom surface or a first surface. In some embodiments, the surface 101 of the substrate 10 is parallel to the surface 112 of the substrate 11. The substrate 11 may include one or more conductive pads 11c in proximity to, adjacent to, or embedded in and exposed at the surface 112 of the substrate 11. The substrate 11 may include a solder resist 11r (or solder mask) on the surface 112 of the substrate 11 to expose at least a portion of the conductive pads 11c for electrical connections.

The antenna pattern 15 is disposed on the surface 112 of the substrate 11. The antenna pattern 15 is disposed on the surface 112 of the substrate 11 corresponding to (e.g. disposed above) the antenna pattern 14 disposed on the surface 101 of the substrate 10. For example, the antenna pattern 15 faces the antenna pattern 14. For example, the antenna pattern 15 may be aligned with the antenna pattern 14. In some embodiments, the antenna pattern 15 includes a plurality of antenna elements. For example, the antenna pattern 15 may include an array of antenna elements. In some embodiments, the antenna pattern 15 may include an M×N array of antenna elements, where M and N are integers greater than 0. In some embodiments, an antenna pattern may be also disposed on the surface 111 of the substrate depending on design specifications.

The electrical contacts 12 are disposed between the substrate 10 and the substrate 11. The electrical contacts 12 are disposed between the surface 101 of the substrate 10 and the substrate 112 of the substrate 11. The electrical contacts 12 are disposed on the conductive pad 10c of the substrate 10 and the conductive pad 11c of the substrate 11. The electrical contacts 12 are in contact with the conductive pad 10c of the substrate 10 and the conductive pad 11c of the substrate 11. In some embodiments, the melting point of the electrical contacts is in a range from about 217° C. to about 225° C. In some embodiments, the electrical contacts 12 may be or include solder balls.

The support elements 13 are disposed between the substrate 10. The support elements 13 are disposed between the surface 101 of the substrate 10 and the substrate 112 of the substrate 11. The support elements 13 are disposed on the solder resist 10r of the substrate 10 and the solder resist 11r of the substrate 11. The support elements 13 are in contact with the solder resist 10r of the substrate 10 and the solder resist 11r of the substrate 11. The support elements 13 adhere to the substrate 10 and the substrate 11. In some embodiments, the support elements 13 have a relatively strong adhesion or bonding to the solder resist 10r and 11r of the substrate 10 and the substrate 11 to avoid the substrate 11 from being peeled off or delaminated from the substrate 10 in the subsequent process.

In some embodiments, the curing temperature of the support elements 13 is higher than the melting point of the electrical contacts 12. In some embodiments, the curing temperature of the support elements 13 is about 225° C. or higher. In some embodiments, the glass transition temperature (Tg) is about 115° C. In some embodiments, the support elements 13 may include a thermosetting material, such as epoxy. In some embodiments, the support elements 13 may include a B-stage adhesive or a cured B-stage adhesive. In some embodiments, the support elements 13 may include a material that is at an A-stage under the room temperature or the temperature less than its Tg (e.g., 115° C.), then become a B-stage under the temperature in a range from its Tg (e.g., 115° C.) to its curing temperature (e.g., 225° C.), and become a C-stage under the temperature over its curing temperature (225° C.). In some embodiments, the time required for the manufacturing process to heat the support elements 13 from its glass transition temperature to its curing temperature is about 200 seconds. In some embodiments, the viscosity of the support elements is about 360 Pa·s.

As shown in FIG. 1A, since the electrical contacts 12 and the support elements 13 are disposed between the substrates 10 and 11 to define a height, a distance, a cavity (e.g. an air cavity) or cavities therebetween, a gain, bandwidth and radiation efficiency of the antenna patterns 14 and 15 can be improved by promoting resonance between the antenna pattern 14 and the antenna pattern 15. To attain a desired level of resonance, a height H11 of the air cavity (e.g. a distance between the antenna pattern 14 and the antenna pattern 15) and a tolerance of the height H11 can be controlled within a certain range. For example, the height H11 of the air cavity can be in a range from about 230 micrometers (μm) to about 280 μm with a tolerance less than ±28 μm. In some embodiments, the height H11 of the air cavity is determined based on the design (e.g., bandwidth or performance) for the antenna patterns 14 and 15.

In some embodiments, the electrical contacts 12 or the support elements 13 may not horizontally overlap the antenna patterns 14 or 15, which can avoid the electromagnetic wave transmitted between the antenna patterns 14 and 15 from being interfered. For example, the electrical contacts 12 or the support elements 13 may have a horizontal displacement relative to the antenna patterns 14 or 15. For example, the electrical contacts 12 or the support elements 13 are horizontally spaced apart from the antenna patterns 14 or 15. For example, a projection of the electrical contacts 12 or the support elements 13 onto the surface 101 of the substrate 10 may not overlap a projection of the antenna patterns 14 or 15 onto the surface 101 of the substrate 10.

In some comparative implementations, the support elements 13 can be omitted and the electrical contacts (e.g. solder balls) are solely used to support the substrate 11. However, the dimension of the solder balls (e.g. a height) may decrease after every reflow process. Therefore, it can be difficult to control the size of each solder ball after the reflow processes, and to control the uniformity of all the solder balls (which can be desirable). Therefore, a large tolerance may exist for the solder balls. For example, it may be desirable to have a height of the solder balls correspond to the height, and the above-described issues may yield a range of variation greater than a desired range of variation (such as ± about 50 μm or greater), which can decrease the efficiency of the resonance of the antenna patterns. Therefore, the solder balls may be applied to the stacked structure with the relatively low requirement for the precision of the height.

In some comparative implementations, the support elements 13 can be implemented by solid state spacers. For example, spacer is disposed between the substrate 10 and the substrate 11. However, the spacer would maintain in a solid state during the manufacturing process, and thus the shape or the height of the spacer is substantially fixed. Therefore, it is difficult to control the amount of solder balls and the height, distance or cavity between the substrate 10 and the substrate 11 during the manufacturing process, which may hinder the connection or bonding between the substrates 10 and 11.

In accordance with some embodiments of the present disclosure, the support elements 13 are implemented by a thermosetting material. During the manufacturing process of the semiconductor device package 1, the process temperature increases gradually, the electrical contacts 12 start to melt when the temperature reach their melting point (e.g., about 217° C. to about 225° C.), and then the support elements 13 are cured as the temperature keeps increasing to reach their curing temperature (e.g., about 225° C.). During the melting process of the electrical contacts 12, the melted electrical contacts can be strongly bonded to the conductive pads 10c and 11c of the substrates 10 and 11 and bring the substrates 10 and 11 closer, providing the self-alignment function for the conductive pads 10c and 11c of the substrates 10 and 11. In addition, when the process temperature reaches the curing temperature of the support elements 13, the support elements 13 are cured or solidified and remain in the cured or solidified state even if the process temperature decreases in the subsequent manufacturing steps, which can allow the air cavity defined by the electrical contacts 12 and the support elements 13 to have a relatively stable and precisely-controlled height compared with the air cavity defined solely by the solder balls. Furthermore, before the curing temperature of the support elements 13 is reached, the height and the shape of the support elements 13 are adjustable, which can flexibly and precisely control the height of air cavity defined by the electrical contacts 12 and the support elements 13 to a desirable value.

FIG. 1B illustrated a top view of the substrate 10 of the semiconductor device package 1 in FIG. 1A in accordance with some embodiments of the present disclosure. As shown in FIG. 1B, the support elements 13 are arranged adjacent to the edges of the substrate 10. The support elements 13 are separated from each other. For example, there is a gap between each of two adjacent support elements 13. In some embodiments, the support elements 13 are separated from the electrical contacts 12.

FIG. 1C illustrated a top view of the substrate 10 of the semiconductor device package 1 in FIG. 1A in accordance with some embodiments of the present disclosure. The arrangement of the support elements 13 and the electrical contacts 12 in FIG. 1C is similar to that in FIG. 1B except that in FIG. 1C, the support elements 13 are further arranged adjacent to the center of the substrate 10, which can provide a better or stable support capability. In some embodiments, the support elements 13 arranged adjacent to the edges of the substrate 10 and the center of the substrate 10 are formed of the same material. Alternatively, the support elements 13 arranged adjacent to the edges of the substrate 10 and the center of the substrate 10 are formed of different materials, which can prevent the warpage issue.

FIG. 1D illustrated a top view of the substrate 10 of the semiconductor device package 1 in FIG. 1A in accordance with some embodiments of the present disclosure. The arrangement of the support elements 13 and the electrical contacts 12 in FIG. 1D is similar to that in FIG. 1B except that in FIG. 1D, the support elements 13 are arranged to form a wall structure around the edges of the substrate 10, which can prevent the warpage issue.

FIG. 1E illustrated a top view of the substrate 10 of the semiconductor device package 1 in FIG. 1A in accordance with some embodiments of the present disclosure. The arrangement of the support elements 13 and the electrical contacts 12 in FIG. 1E is similar to that in FIG. 1C except that in FIG. 1E, the support elements 13 are arranged to form a wall structure around the edges of the substrate 10, which can provide a better or stable support capability.

FIG. 1F illustrated an enlarged view of a portion of the semiconductor device package 1 in FIG. 1A circled by a dotted-line rectangle A in accordance with some embodiments of the present disclosure. As shown in FIG. 1F, the support element 13 has an inwardly-recessed sidewall 13a. For example, the sidewall 13a of the support element 13 is inwardly recessed. For example, the support element 13 has a neck-shaped sidewall. For example, the thickness of the support elements 13 in contact with the solder resist 10r or 11r is greater than the thickness of the middle portion of the support elements 13.

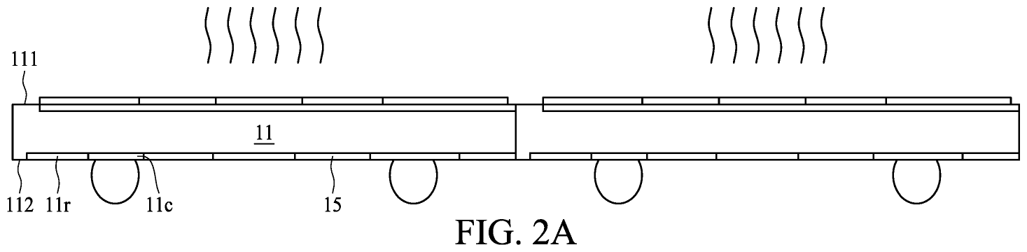

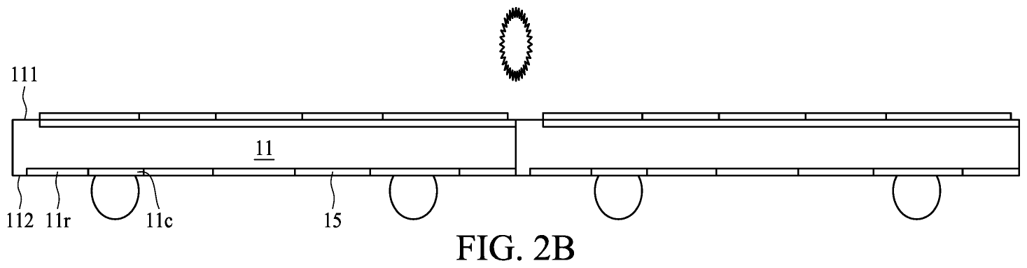

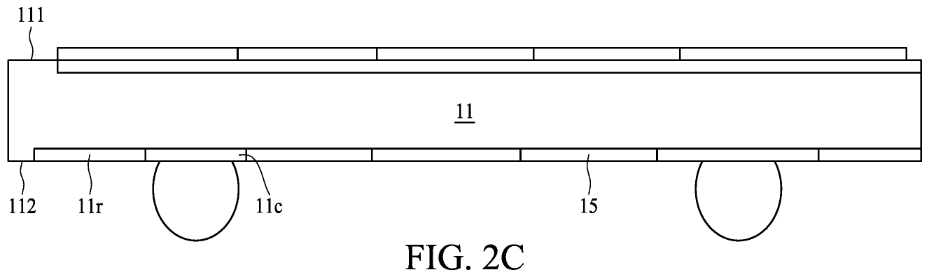

FIG. 2A, FIG. 2B and FIG. 2C are cross-sectional views of a semiconductor structure at various stages of fabrication, in accordance with some embodiments of the present disclosure. Various figures have been simplified to provide a better understanding of the aspects of the present disclosure. In some embodiments, the method illustrated in FIG. 2A, FIG. 2B and FIG. 2C are used to form the substrate 11 and the electrical contacts 12 in FIG. 1A.

Referring to FIG. 2A, a strip of substrates including the substrate 11 is provided. The substrate 11 has conductive pads 11c, solder resist 11r and an antenna pattern 15 is provided. Electrical contacts 12 (e.g., solder balls) are disposed or mounted on the conductive pads 11c of the substrate 11.

Referring to FIG. 2B, a singulation process is carried out to separate out individual substrates as shown in FIG. 2C. That is, the singulation is performed through the substrate strip including the substrate 11. The singulation may be performed, for example, by using a dicing saw, laser or other appropriate cutting technique.

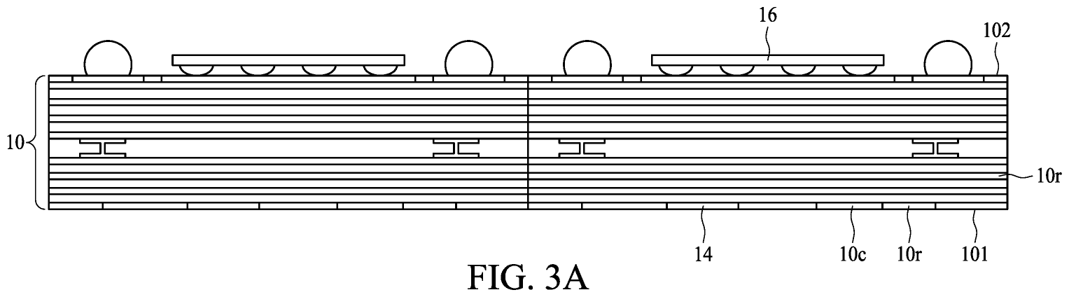

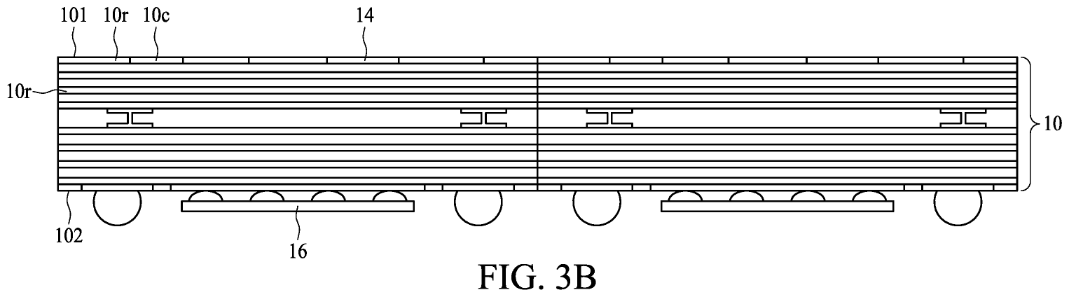

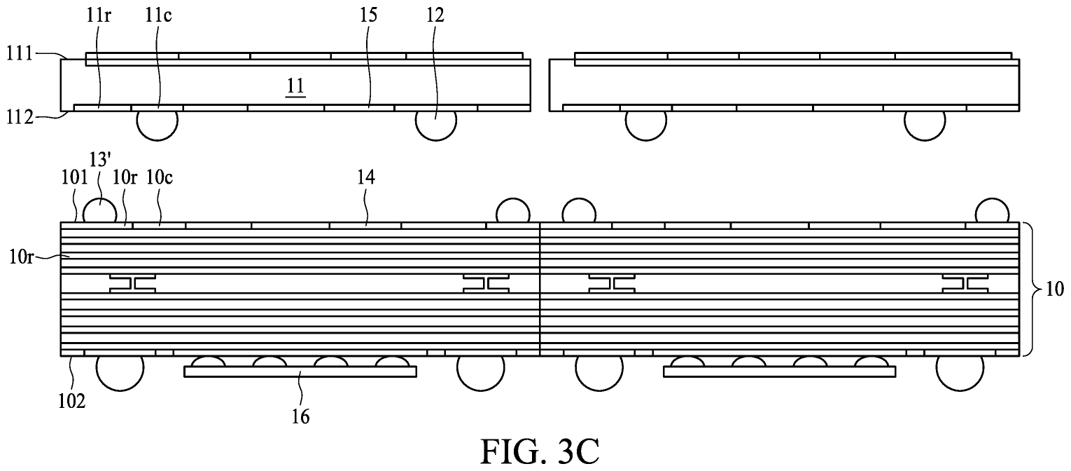

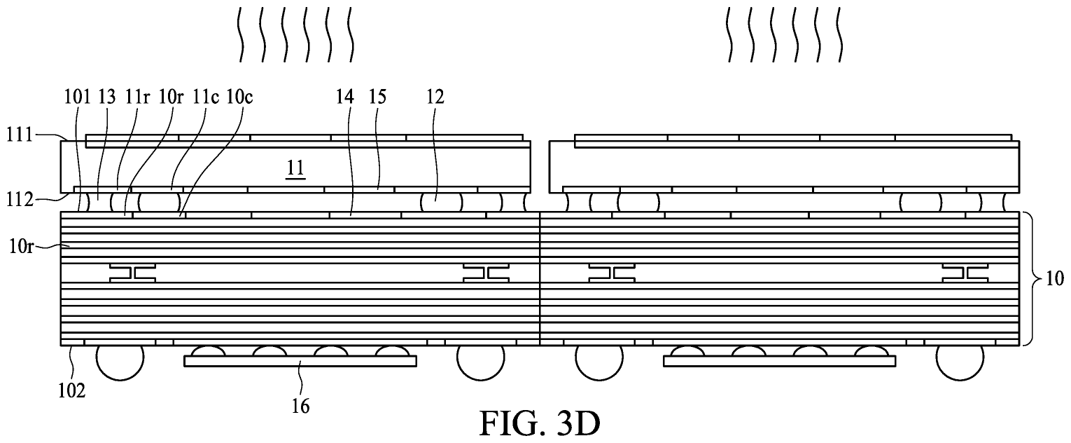

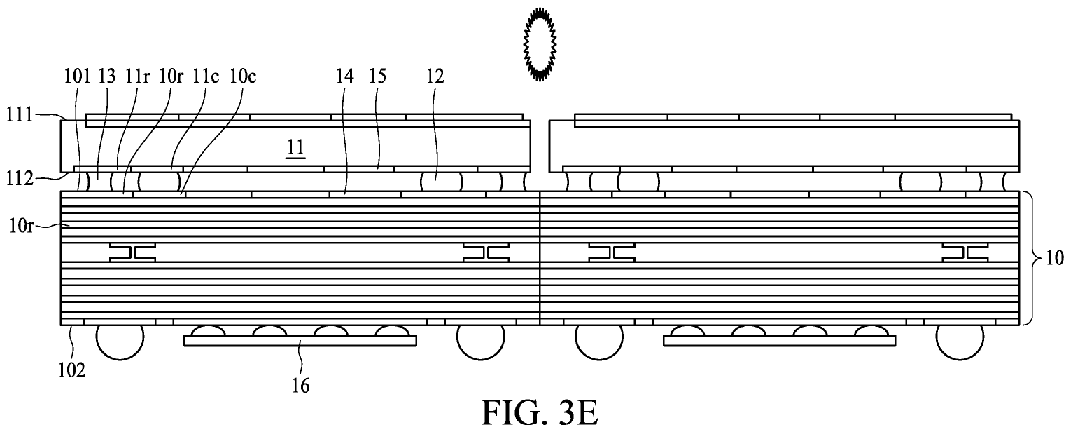

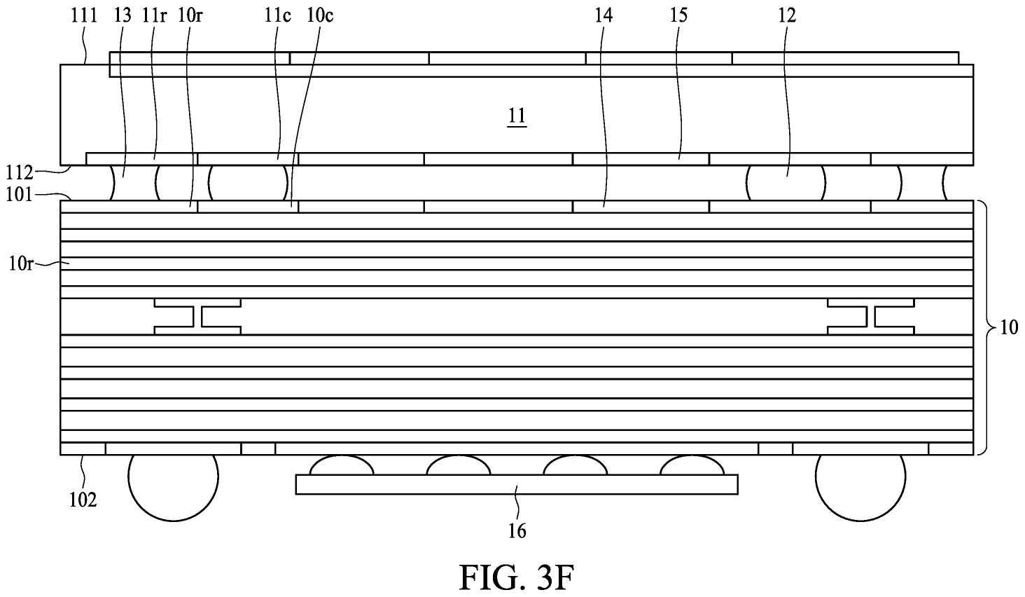

FIG. 3A, FIG. 3B, FIG. 3C, FIG. 3D, FIG. 3E and FIG. 3F are cross-sectional views of a semiconductor structure at various stages of fabrication, in accordance with some embodiments of the present disclosure. Various figures have been simplified to provide a better understanding of the aspects of the present disclosure. In some embodiments, the method illustrated in FIG. 3A, FIG. 3B, FIG. 3C, FIG. 3D, FIG. 3E and FIG. 3F are used to form the semiconductor device package 1 in FIG. 1A.

Referring to FIG. 3A, a strip of substrates including the substrate 10 is provided. The substrate 10 has conductive pads 10c, solder resist 10r and an antenna pattern 14 is provided. The electronic component 16 and solder balls are disposed or mounted on the surface 102 of the substrate 10. Then the structure in FIG. 3A is turned over as shown in FIG. 3B.

Referring to FIG. 3C, a thermosetting material 13′ (A-stage adhesive or B-stage adhesive) is applied on the solder resist 10c of the substrate 10. In some embodiments, the thermosetting material 13′ is in a form of gel or glue under the room temperature or the temperature less than its Tg (e.g., 115° C.). For example, the thermosetting material 13′ is at the A-stage. The structure in FIG. 2C is disposed on the surface 101 of the substrate 10. For example, the electrical contacts 12 are disposed or placed on the conductive pads 10c of the substrate 10.

Referring to FIG. 3D, a thermal process is carried out to the structure in FIG. 3C. For example, the structure in FIG. 3C is heated. In some embodiments, when the process temperature reaches the melting point (e.g., 217° C.) of the electrical contacts 12, the electrical contacts 12 start to melt to be strongly bonded to the conductive pads 10c and 11c of the substrates 10 and 11 and to bring the substrates 10 and 11 closer, providing the self-alignment function for the conductive pads 10c and 11c of the substrates 10 and 11. When the process temperature keeps increasing to reach the curing temperature (e.g., about 225° C.) of the thermosetting material 13′, the thermosetting material 13′ is cured or solidified to form the support element 13. For example, the thermosetting material 13′ is at the C-stage. The support element 13 remains in the cured state or the solidified state even if the process temperature decreases in the subsequent manufacturing steps, allowing the air cavity defined by the electrical contacts 12 and the support elements 13 to have a relatively stable height. Furthermore, before the curing temperature of the support elements 13 has been reached, the height or the shape of the support elements 13 are adjustable, which can flexibly and precisely control the height of air cavity defined by the electrical contacts 12 and the support elements 13 to a desirable value. In some embodiments, the time required for the manufacturing process to heat the support elements 13 from its glass transition temperature (e.g., 115° C.) to its curing temperature is about 200 seconds.

Referring to FIG. 3E, singulation may be performed to separate out individual semiconductor package devices as shown in FIG. 3F. That is, the singulation is performed through the substrate strip including the substrate 10. The singulation may be performed, for example, by using a dicing saw, laser or other appropriate cutting technique.

As used herein, the terms “approximately,” “substantially,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

1. A semiconductor device package, comprising:
a first substrate having a first surface;
a second substrate having a first surface facing the first surface of the first substrate;
an electrical contact disposed between the first substrate and the second substrate; and
a support element disposed between the first substrate and the second substrate, wherein the support element includes a thermosetting material.

2. The semiconductor device package of claim 1, wherein the support element includes a cured B-stage adhesive.

3. The semiconductor device package of claim 1, wherein a curing temperature of the support element is higher than a melting point of the electrical contact.

4. The semiconductor device package of claim 1, wherein
the first surface of the first substrate includes a conductive pad; and
the first surface of the second substrate includes a conductive pad; and the electrical contact is in contact with the conductive pads of the first substrate and the second substrate.

5. The semiconductor device package of claim 1, wherein the first surface of the first substrate includes a solder resist, and the first surface of the second substrate includes a solder resist; wherein the support element is in contact with the solder resists of the first substrate and the second substrate.

6. The semiconductor device package of claim 1, further comprising:
a first antenna pattern disposed on the first surface of the first substrate; and
a second antenna pattern disposed on the first surface of the second substrate and corresponding to the first antenna pattern,
wherein the first antenna pattern or the second antenna has a horizontal displacement relative to any of the electrical contact and the support element.

7. The semiconductor device package of claim 1, further comprises a plurality of support elements, wherein the support elements are disposed along edges of the first surface of the first substrate.

8. The semiconductor device package of claim 1, further comprises a plurality of support elements, wherein the support elements are disposed adjacent to the center of the first surface of the first substrate.

9. The semiconductor device package of claim 1, wherein the support element has an inwardly-recessed sidewall.

10. The semiconductor device package of claim 1, wherein the support element adheres to the first substrate and the second substrate.

11. A semiconductor device package, comprising:
a first substrate having a first surface;
a second substrate having a first surface facing the first surface of the first substrate;
an electrical contact disposed between the first substrate and the second substrate; and
a support element disposed between the first substrate and the second substrate, wherein a curing temperature of the support element is higher than a melting point of the electrical contact.

12. The semiconductor device package of claim 11, wherein the support element includes a cured B-stage adhesive.

13. The semiconductor device package of claim 11, wherein the support element includes epoxy.

14. The semiconductor device package of claim 11, wherein
the first surface of the first substrate includes a conductive pad and a solder resist covering a portion of the conductive pad; and
the first surface of the second substrate includes a conductive pad and a solder resist covering a portion of the conductive pad.

15. The semiconductor device package of claim 11, wherein the first surface of the first substrate includes a solder resist, and the first surface of the second substrate includes a solder resist; wherein the support element is in contact with the solder resists of the first substrate and the second substrate.

16. The semiconductor device package of claim 11, further comprising:
a first antenna pattern disposed on the first surface of the first substrate; and
a second antenna pattern disposed on the first surface of the second substrate and corresponding to the first antenna pattern,
wherein the first antenna pattern or the second antenna has a horizontal displacement relative to any of the electrical contact and the support element.

17. The semiconductor device package of claim 11, further comprises a plurality of support elements, wherein the support elements are disposed along edges of the first surface of the first substrate.

18. The semiconductor device package of claim 11, further comprises a plurality of support elements, wherein the support elements are disposed adjacent to the center of the first surface of the first substrate.

19. The semiconductor device package of claim 11, wherein the support element has an inwardly-recessed sidewall.

20. The semiconductor device package of claim 11, wherein the support element adheres to the first substrate and the second substrate.

21-23. (canceled)
